(19) United States
(12) Patent Application Publication
(10) Pub. No.: US 2004/0023509 A1
(43) Pub. Date: Feb. 5, 2004

(54) Electron beam mask substrate, electron beam mask blank, electron beam mask, and fabrication method thereof

(75) Inventor: Isao Amemiya, Yamanashi (JP)

Correspondence Address: SUGHRUE MION, PLLC, 2100 PENNSYLVANIA AVENUE, N.W., WASHINGTON, DC, 20037, US

(73) Assignee: HOYA CORPORATION

(21) Appl. No.: 10/442,051

(22) Filed: May 21, 2003

(30) Foreign Application Priority Data
May 21, 2002 (JP) P. 2002-146882

(51) Int. Cl. H01L 21/302; H01L 21/461

(52) U.S. Cl. 438/720

(57) ABSTRACT

An electron beam mask substrate including a substrate layer to form a membrane layer support through backside etching, an etching stopper layer formed on the substrate layer, and a membrane layer formed on the etching stopper layer. When the tensile stress of the membrane layer is reduced with the reduction in the thickness of the layer and when the membrane part having the membrane layer and the etching stopper layer is deformed during backside processing owing to the influence of the stress of the etching stopper layer thereon, and/or when the membrane layer is deformed within a range not satisfying the mask pattern positioning accuracy during removal of the etching stopper layer, then the membrane stress of the membrane layer and the membrane stress of the etching stopper layer are so correlated that the membrane part is not deformed during backside processing, and/or so correlated that the membrane layer is not deformed over the range satisfying the mask pattern positioning accuracy during removal of the etching stopper layer. This allows for the production of a tough electron beam mask for which the membrane stress of the etching stopper is specifically so controlled as to reduce the deformation of the layer structure, and to provide an electron beam mask substrate and an electron beam mask blank which are for producing the electron beam mask.

### BACKGROUND OF THE INVENTION

1. Field of the Invention

The present invention relates to structures of a transfer mask and a mask blank that are used in electron beam lithography for fabricating semiconductor devices and other devices by the use of charged particle beams, especially electron beams, and to a method for producing these structures.

2. Description of the Related Art

Like ordinary exposure technology for step-and-repeat systems using a related art photo-reticle and an ordinary stepper and like that for 1:1 exposure systems using a related art photomask, electron beam exposure technology for step-and-repeat systems using an electron beam reticle and an EB stepper and that for 1:1 lithography for low energy electron beam systems using an LEEPL mask have been proposed recently, and they are now being rapidly realized for solving various problems in the art.

EPL (electron projection lithography) masks (of stencil type and membrane type) and LEEPL (low-energy electron beam projection lithography) masks (of stencil type) for these are required to be enlarged at least up to an 8-inch size for enhancing their practicability. Specifically, when an 8-inch-size EPL reticle is used, then a mask pattern for one layer may be mounted on one EPL reticle of that size, and when an 8-inch-size LEEPL mask is used, then a mask pattern for all chips may be transferred at a time onto an 8-inch-size silicon wafer.

In these EPL masks and LEEPL masks, the thickness standard of the membrane layer to form the mask pattern is, at most, approximately 2 μm and the layer is extremely thin (specifically, it is 2 μm in the former, and is 0.5 μm in the latter). As compared with the membrane layer having a thickness of approximately 10 μm in stencil masks for related art electron beam exposure (cell projection delineation method), the membrane layer in these masks is extremely thin, and therefore these masks are difficult to fabricate.

In addition, the quality of these EPL masks and LEEPL masks must be on a level with that of related art photo-reticules and photomasks. This is because, as compared with the reduction ratio of from 1/26 to 1/60 in electron beam masks for cell projection delineation method, the reduction ratio in EPL masks is 1/4 and that in LEEPL masks is 1/1. In addition, for example, the mask pattern size in 8-inch EPI masks is from 0.2 to 0.3 μm (from 50 to 70 nm on wafer). Especially for ensuring mask pattern positioning accuracy, the stress that may occur in the membrane layer to form a mask pattern must be well controlled, but the mask pattern position control is difficult in point of the in-plane distribution characteristics the mask pattern to be formed, when the membrane layer has a thickness of at most 2 μm or so and is extremely thin and when the mask size is enlarged to, for example, 8 inches or so.

In fabricating these EPL masks (especially of stencil type) and LEEPL masks, at present, one general and realistic method comprises preparing and using SOI (silicon-on-insulator) wafers of Si/SiO₂/Si structure. However, when such an SOI wafer is used as the mask substrate, then the compression stress of the silicon dioxide (SiO₂) layer which is formed on it as an etching stopper will be extremely large and it therefore causes stress change in the Si membrane layer. This is described more specifically with reference to FIG. 4.

As shown in FIG. 4(1), one standard specification proposed for the layer thickness of SOI substrates for 8-inch-size stencil-type EPL masks includes: 2 μm for the Si membrane layer, 1 μm for the SiO₂ etching stopper layer, and from 725 to 750 μm (for 8-inch-size) for the support layer (FIG. 4(1)).

It has been found that, since the SiO₂ etching stopper layer has strong compression stress, the membrane layer formed is greatly deformed (warped) owing to the influence of the compression stress layer thereon during backside working, as in FIG. 4(2), and therefore comes to be readily and seriously damaged or broken (hereinafter this is referred to as problem 1-1).

In addition, it has also been found that, after the SiO₂ layer exposed outside through the windows on the back face has been removed, the Si membrane layer is also deformed (warped) as in FIG. 4(3), if its tensile stress is not sufficiently large. This is because the flexural stress in the compression direction of the SiO₂ layer acts on the Si membrane layer, as in FIG. 5 (hereinafter this is referred to as problem 1-2).

One method that has heretofore been proposed for solving these problems comprises doping the Si membrane layer with an impurity such as boron (B) to an extremely high dopant concentration to thereby increase the tensile stress of the resulting Si membrane layer. This is done to make the Si membrane layer self-sustainable.

However, this method is problematic in that its takes a long time for the high-concentration doping and produces a dopant concentration profile in the depth direction of the Si layer. Still another problem with the method is that it is extremely difficult to control the membrane stress of the Si membrane layer to at most 10 MPa after the mask formation for satisfying the pattern positioning accuracy. This is because the thick SiO₂ layer having a thickness of 1 μm and having large compression stress is selectively removed as mentioned above, after it has become useless for the etching stopper layer in the process of mask fabrication. To satisfy the process condition and to make the Si layer finally have a membrane stress of at most 10 MPa, reproducible control of the dopant concentration in the Si membrane layer and reproducible control of the thickness of the SiO₂ layer are indispensable requirements, which, however, are really extremely difficult from a practical viewpoint.

Another method that may be taken into consideration for solving the problems with the SOI wafer substrate is described as follows. When doped to have an ordinary dopant concentration of from 10¹⁴ to 10¹⁵ atm/cm³, the Si layer may have stress in the tensile direction (tensile stress) by itself. Therefore, a method of reducing the flexural stress of the SiO₂ layer at the window edges after the backside processing will be effective. For reducing the flexural stress of the SiO₂ layer, the inner stress of the SiO₂ layer shall be reduced or the SiO₂ layer shall be thinned. It is difficult to reduce the inner stress itself of the layer in the current technology of SOI wafer fabrication. Therefore, the method of reducing the compressive flexural stress of the SiO₂ layer is limited to the reduction in the thickness of the SiO₂ layer.

FIG. 6 shows the stress change in an Si membrane layer actually measured according to a Bulge method in which the thickness of the SiO₂ layer was changed. The Si membrane layer was doped with boron (B), and the dopant concentration was 8×10¹⁵ atm/cm². As shown in FIG. 6, the stress of the Si membrane layer varied depending on the thickness of the SiO₂ layer. When the range of the stress of the Si membrane layer is defined to fall between 1 and 10 MPa, then the suitable SiO₂ thickness is about 0.3 μm (300 nm).

However, the indispensable requirement for the SiO₂ layer is that it should function as an etching stopper in both backside etching and surface etching. Therefore, anytime having such a defined thickness, the SiO₂ layer must have good etching selectivity. A test for actually confirming the etching selective ratio was carried out. In mask patterning (surface patterning), the selective ratio to silicon (Si) was about 10; while in backside processing, the etching selective ratio increased with the increase in the chamber pressure during etching, as in FIG. 7, but the characteristic was not satisfactory. Further, as in the drawing, it was recognized that the in-plane distribution uniformity of the etching rate lowered, contradictory to the increase in the etching selective ratio. This characteristic becomes more significant with the increase in the substrate size. For example, in a 4-inch-size substrate, the in-plane etching rate distribution uniformity was at least 95% when the selective ratio was 100; but in an 8-inch-size substrate, the in-plane etching rate distribution uniformity lowered to at most 60% when the selective ratio was 100. The reason is because of the non-uniformity of the part within the area of the substrate to be etched (that is, the etching rate at the outer peripheral part of the substrate is high, but the etching rate at the center part thereof is low). Therefore, even in the most up-to-date high-performance etching device now available on the market, the etching rate uniformity is at most 80% when the etching condition is so controlled such that the Si/SiO₂ etching selective ratio is at least 300.

From the above-mentioned results, it has become obvious that the two requirements of thinning the SiO₂ membrane layer and improving its property as an etching stopper are difficult to satisfy simultaneously, and therefore 8-inch-size stencil masks could not be fabricated (this is hereinafter referred to as problem 2).

### SUMMARY OF THE INVENTION

The present invention has been made in consideration of the above-mentioned problems, and an object thereof is to provide a tough electron beam mask for which the membrane stress of the etching stopper is specifically so controlled as to reduce the deformation of the layer structure, and to provide an electron beam mask substrate and an electron beam mask blank which are for producing the electron beam mask.

Another object of the invention is to provide an electron beam mask substrate and an electron beam mask blank for which the etching stopper is specifically so improved as to exhibit good characteristics in backside processing, and to provide an electron beam mask produced from them.

Still another object of the invention is to provide an electron beam mask substrate and an electron beam mask blank capable of giving large-sized electron beam masks in which the size of the substrate is large (for example, an 8-inch-size), and to provide an electron beam mask produced from them.

In a first embodiment of the invention, an electron beam mask substrate comprises a substrate layer to form a membrane layer support through backside etching, an etching stopper layer formed on the substrate layer, and a membrane layer formed on the etching stopper layer, wherein;

when a tensile stress of the membrane layer is reduced with a reduction in a thickness of the membrane layer so that a membrane part comprising the membrane layer and the etching stopper layer is deformed by backside etching processing, and/or the membrane layer is deformed within a range not satisfying a mask pattern positioning accuracy by removal of the etching stopper layer, owing to the influence of a stress of the etching stopper layer thereon,

then the membrane stress of the membrane layer and the membrane stress of the etching stopper layer are so correlated that the membrane part is not deformed during backside processing, and/or so correlated that the membrane layer is not deformed over the range satisfying the mask pattern positioning accuracy during removal of the etching stopper layer.

In a second embodiment of the invention, an electron beam mask substrate comprising a substrate layer to form a membrane layer support through backside etching, an etching stopper layer formed on the substrate layer, and a membrane layer formed on the etching stopper layer, wherein;

an etching selective ratio of the etching stopper layer to the substrate layer is sufficiently enlarged for the purpose of ensuring good latitude in dry-etching conditions in backside dry-etching.

In a third embodiment, an electron beam mask substrate comprising a substrate layer of a silicon-containing material to form a membrane layer support through backside etching, an etching stopper layer formed on the substrate layer, and a membrane layer of a silicon-containing material formed on the etching stopper layer, wherein;

the etching stopper layer is formed of a low-stress material that gives a membrane stress falling within a range of about ±30 MPa after backside etching, or is formed of a low-stress material capable of controlling the membrane stress after backside etching to fall within a range of about ±30 MPa. Alternatively, the low-stress material would be operable to have both of these features.

In a fourth embodiment, an electron beam mask substrate comprises a substrate layer of a silicon-containing material to form a membrane layer support through backside etching, an etching stopper layer formed on the substrate layer, and a membrane layer of a silicon-containing material formed on the etching stopper layer, wherein;

the etching stopper layer is formed of a material of which the etching selective ratio to the silicon-containing substrate layer is at least about 700. Further, in a fifth embodiment, an electron beam mask substrate comprises a substrate layer of a silicon-containing material to form a membrane layer support through backside etching, an etching stopper layer formed on the substrate layer, and a membrane layer of a silicon-containing material formed on the etching stopper layer, wherein;

the etching stopper layer is formed of any one selected from a metal material, a metal compound, carbon and a carbon compound, or a combination of any of these. In a sixth embodiment, the metal compound of the electron beam mask substrate of embodiment 5 is a chromium compound.

In a seventh embodiment, the metal compound of the electron beam mask substrate of embodiment 5 is any one selected from compounds with any of titanium (Ti), tantalum (Ta), zirconium (Zr), aluminium (Al), molybdenum (Mo) and tungsten (W), or a combination of any of these.

An eighth embodiment includes an electron beam mask blank, which is produced through backside etching of the electron beam mask substrate of any of embodiments 1 to 7 to form a support.

A ninth embodiment includes an electron beam mask, which is produced through backside etching of the electron beam mask substrate of any of embodiments 1 to 7, combined with surface etching thereof to form a mask pattern.

A tenth embodiment is a method for producing an electron beam exposure mask, which comprises processing an electron beam mask substrate having the material of embodiments 6 or 7 for producing the mask, and in which the essential dry-etching gas for mask-patterning the membrane layer is any of sulfur hexafluoride (SF₆) or carbon tetrafluoride (CF₄) when a resist is used for the etching mask, but is any of silicon tetrachloride (SiCl₄), hydrogen chloride (HCl), hydrogen bromide (HBr) or hydrogen iodide (HI) when silicon dioxide (SiO₂) is used for the etching mask, and one or more fluorine-containing gases selected from SF₆, C₄F₈, C₃F₈, C₄F₆, C₂F₆ and C₅F₈ are used in backside dry-etching.

### BRIEF DESCRIPTION OF THE DRAWINGS

FIG. 1. is a graph showing the relationship between the bias power and the etching selective ratio for demonstrating the effect of the invention;

FIG. 2. is a schematic view for explaining the production process of fabricating a mask as one embodiment of the invention;

FIG. 3 is a partly-cut perspective view for explaining a strut structure of the mask substrate of the invention;

FIG. 4 is a schematic view for explaining the problem of deformation in the related art;

FIG. 5 is a schematic view for explaining the problem of flexural stress of an etching stopper layer in the related art;

FIG. 6 is a graph showing the relationship between the thickness of an SiO₂ etching stopper layer and the membrane stress of an Si membrane layer for explaining the problem in the related art; and

FIG. 7 is a graph showing the relationship between the chamber pressure and the Si/SiO₂ etching selective ratio for explaining the problem in the related art.

### DETAILED DESCRIPTION OF THE INVENTION

The first aspect of the invention has been attained for solving the above-mentioned problems 1-1 and 1-2, and includes an electron beam mask substrate that comprises a substrate layer to form a membrane layer support through backside etching, an etching stopper layer formed on the substrate layer, and a membrane layer formed on the etching stopper layer, wherein;

when a tensile stress of the membrane layer is reduced with a reduction in a thickness of the membrane layer so that a membrane part comprising the membrane layer and the etching stopper layer is deformed by backside etching processing, and/or the membrane layer is deformed within a range not satisfying a mask pattern positioning accuracy by removal of the etching stopper layer (accordingly in completion of the mask), owing to the influence of the compression stress and the flexural stress of the etching stopper layer thereon,

then the membrane stress of the membrane layer and the membrane stress of the etching stopper layer are so correlated that the membrane part is not deformed during backside processing, and/or so correlated that the membrane layer is not deformed over the range satisfying the mask pattern positioning accuracy during removal of the etching stopper layer (Embodiment 1).

This does not require any complicated operations of controlling and adjusting the film-forming condition and the film thickness for the purpose of evading the above-mentioned problems 1-1 and 1-2.

In the first aspect of the invention, it is desirable that the membrane stress of the membrane layer and the membrane stress of the etching stopper layer are so correlated that the membrane part is not deformed during backside processing, and so correlated that the membrane layer is not deformed over the range satisfying the mask pattern positioning accuracy during removal of the etching stopper layer.

In the first aspect of the invention, it is desirable that the initial membrane stress correlation in fabricating the electron beam mask substrate satisfies the above-mentioned requirement. This facilitates the mask fabrication very well. In the first aspect of the invention, the stress correlation may be controlled to satisfy the above-mentioned requirement just before the backside processing and/or just before the etching stopper layer removal in the process of processing the electron beam mask substrate.

The first aspect of the invention is especially effective when the thickness of the membrane layer is not larger than 2 μm. This is because the degree of membrane deformation is defined by the product of the inner stress of the membrane and the membrane thickness. Therefore, when the membrane layer is extremely thin, then its tensile stress is small, and, as a result, the compression stress of the etching stopper layer (SiO₂ layer) is larger than the tensile stress of the membrane layer and the membrane layer is thereby apt to be extremely deformed.

It is also desirable that the etching stopper layer is formed of a low-stress material or a material capable of reducing the membrane stress of the layer. Accordingly, the frequency of the above-mentioned problems 1-1 and 1-2 may be greatly reduced, and the latitude in mask fabrication can be significantly broadened.

In the case where the backside-processed substrate is further processed into a stencil mask and when the membrane stress of the etching stopper layer in the substrate is low, the etching stopper layer may be used as it is in the subsequent surface working step (for forming windows). If, however, the stress of the etching stopper layer is large, the membrane part will be deformed and will be damaged or broken, and, as a result, the etching stopper layer could no more be used as it is for an etching stopper in surface processing. Accordingly, the etching stopper layer may be removed before surface processing. However, if no etching stopper exists in surface processing, the working gas (such as a dry-etching gas) will run to the back face when the mask patterning has been finished to form through-hole windows, and it will cause a problem of corrosion. Apart from this, another etching stopper for surface processing may be formed after the removal of the backside etching stopper. However, this is still problematic in that a uniform film for the stopper is difficult to form owing to the step difference on the backside face. Accordingly, it is desirable that the etching stopper for backside processing shall act also for surface processing.

In the first aspect of the invention, the etching stopper layer may be formed of a low-stress material or a material capable of reducing the membrane stress of the layer, for the purpose of evading the sub-field (membrane part) damage; or the etching stopper layer may be controlled to have low stress also for the purpose of evading the sub-field damage. For this, FIG. 3 is referred to.

Basically, the first aspect of the invention is applicable to any case, irrespective of the substrate size. This is because, for example, even a 4-inch-size substrate has a possibility of sub-field damage therein (though the possibility may be low), and the invention is effective for evading the sub-field damage possibility. However, the sub-field damage possibility is high in large-size substrates (for example, an 8-inch-size substrate has 8000 sub-fields, and even if one of them is damaged broken, the substrate is essentially useless; and sub-field damage becomes remarkable in 8-inch-size substrates, and masks could not be produced from such damaged substrates). Accordingly, the first aspect of the invention is especially effective for large-size substrates (for example, those larger than 4-inch substrates, especially those not smaller than 8-inch substrates). Of course, these desirable described sizes do not preclude the present invention's applicability to substrate sizes other than those described in this range.

The first aspect of the invention is extremely effective in fabricating stencil-type EPL masks, membrane-type EPL masks, and LEEPL masks. In stencil-type EPL masks and LEEPL masks, through-holes are formed in the membrane layer to form the mask pattern. In membrane-type EPL masks, an electron beam scatterer layer is formed on the membrane layer, and this is patterned to form the mask pattern.

In the first aspect of the invention, it is desirable that the material of the etching stopper layer has dry-etching resistance. Specifically, it is desirable that the material has dry-etching resistance to backside dry-etching and optionally to surface dry-etching to such a degree that at least a half (½) of the thickness of the etching stopper layer may remain after dry-etching. Also preferably, the material of the etching stopper layer has chemical resistance in view of the resistance of the layer to mask washing. Further, it is preferable that the material of the etching stopper layer has thermal stability for ensuring the stability thereof in heating with electron beams and for evading the stress change under heat therewith. In addition, it is preferable that the material of the etching stopper layer has good film-formability capable of stably forming high-quality films.

In the first aspect of the invention, the membrane layer is preferably formed of silicon or a silicon-containing material. High-quality membrane layers are stably formed of silicon or a silicon-containing material, and the layers are readily processed with great accuracy.

In the first aspect of the invention, the substrate layer to form the support is preferably formed of silicon or a silicon-containing material. Substrates of high surface smoothness and high quality are stably available in this embodiment and are readily processed with great accuracy.

The first aspect of the invention is applicable, for example, to any fabrication using backside dry-etching or wet-etching.

The second aspect of the invention has been attained for solving the above-mentioned problem 2, and includes an electron beam mask substrate that comprises a substrate layer to form a membrane layer support through backside etching, an etching stopper layer formed on the substrate layer, and a membrane layer formed on the etching stopper layer, wherein;

the etching selective ratio of the etching stopper layer to the substrate layer is sufficiently enlarged for the purpose of ensuring good latitude in dry-etching conditions in backside dry-etching (Embodiment 2).

This does not require any complicated operations of controlling the dry-etching conditions in backside dry-etching for the purpose of increasing the etching selective ratio. In addition, this significantly improves the process stability against the fluctuation of dry-etching conditions. Further, since the etching selective ratio is sufficiently enlarged in this aspect, it is possible to also increase the etching selective ratio in surface etching in the subsequent surface-etching step.

In the second aspect of the invention, the etching selective ratio of the etching stopper layer to the substrate layer may be sufficiently enlarged for the purpose of ensuring good latitude in in-plane etching rate uniformity, when the in-plane etching rate uniformity in backside dry-etching worsens with the increase in the size of the membrane layer (substrate layer). Accordingly, the problem of apparatus limitation in backside processing may be solved, not severely requiring the in-plane etching rate uniformity in a backside dry-etching device. The substrate fabrication is therefore simplified, and the costs for it are reduced. Accordingly, even large-size-masks (for example, those larger than a 4-inch-size, especially those of an 8inch-size or more), for which the in-plane etching rate uniformity is lower than usual (for example, about 90%), may be fabricated according to the second aspect of the invention.

In the second aspect of the invention, the etching selective ratio of tile etching stopper layer to the substrate layer may be sufficiently enlarged for the purpose of preventing the over-etching time from being prolonged in backside dry-etching in which the over-etching time may be prolonged with the increase in the size of the membrane layer (substrate layer) and with the increase in the thickness of the substrate layer. If the etching selective ratio is not sufficiently large, the etching stopper layer is etched away, and, if so, the surface Si layer is also readily etched away.

In the second aspect of the invention, the etching selective ratio of the etching stopper layer to the substrate layer may be sufficiently enlarged for facilitating the fabrication of election beam masks even when the conditions in processing SiO₂ on an SOI substrate to fabricate electron beam masks are severer with the increase in the size of the membrane layer (substrate layer) (for example, when the two requirements of preventing the membrane layer damage owing to the reduction in the membrane stress of the etching stopper layer and keeping the properties of the etching stopper layer are difficult to satisfy simultaneously).

In the second aspect of the invention, it is desirable that the etching stopper layer is formed of a material of which the etching selective ratio to the substrate layer is sufficiently large.

In the second aspect of the invention, it is also desirable that the etching stopper layer is formed of a material that is selectively removable. More preferably, the etching stopper layer is formed of a material of which the selective removal is easy. Also preferably, the material for the etching stopper layer has a high etching rate and good etching rate uniformity. This is because, while the etching stopper layer formed of the material of the preferred type is selectively removed, it is prevented from being over-etched and therefore the damage to the membrane layer may be reduced.

In the second aspect of the invention, it is further desirable that the material of the etching stopper layer has dry-etching resistance. Also preferably, the material of the etching stopper layer has chemical resistance in view of the resistance of the layer to mask washing. In addition, the material of the etching stopper layer may have thermal stability for ensuring the stability thereof in heating with electron beams and for evading the stress change under heat therewith. Still further, it is desirable that the material of the etching stopper layer has good film-formability capable of stably forming high-quality films.

The second aspect of the invention is extremely effective for fabricating stencil-type EPL masks, membrane-type EPL masks and LEEPL masks.

The third aspect of the invention has been attained for solving the above-mentioned problems 1-1 and 1-2, and includes an electron beam mask substrate that comprises a substrate layer of a silicon-containing material to form a membrane layer support through backside etching, an etching stopper layer formed on the substrate layer, and a membrane layer of a silicon-containing material formed on the etching stopper layer, wherein;

the etching stopper layer is formed of a low-stress material that gives a membrane stress falling within a range of about ±30 MPa after backside etching, or is formed of a low-stress material capable of controlling the membrane stress after backside etching to fall within a range of about ±30 MPa (Embodiment 3).

The third aspect of the invention more effectively solves the above-mentioned problems 1-1 and 1-2.

In the third aspect of the invention, the etching stopper layer may be formed of a low-stress material that gives a membrane stress falling within a range of about ±30 MPa, or is formed of a low-stress material capable of controlling the membrane stress to fall within a range of about ±30 MPa, for the purpose of evading the damage to the sub-field (membrane part) as shown in FIG. 3. Alternatively, the low-stress material would be operable to have both of these features.

More preferably, the membrane stress fall within a range of about ±20 MPa.

The other features of this embodiment are similar to those of the first embodiment of the invention, and as such, will not be described.

The fourth aspect of the invention has been attained for solving the above-mentioned problem 2, and includes an electron beam mask substrate that comprises a substrate layer of a silicon-containing material to form a membrane layer support through backside etching, an etching stopper layer formed on the substrate layer, and a membrane layer of a silicon-containing material formed on the etching stopper layer, wherein;

the etching stopper layer is formed of a material of which the etching selective ratio to the silicon-containing substrate layer is at least about 700 (Embodiment 4).

The fourth aspect of the invention more effectively solves the above-mentioned problem 2.

In the fourth aspect of the invention, the etching selective ratio of the etching stopper layer to the substrate layer may be at least about 700 for the purpose of ensuring good latitude in in-plane etching rate uniformity, when the in-plane etching rate uniformity in backside dry-etching worsens with the increase in the size of the membrane layer (substrate layer).

In the fourth aspect of the invention, the etching selective ratio of the etching stopper layer to the substrate layer may be at least about 700 for the purpose of preventing the over-etching time from being prolonged in backside dry-etching in which the over-etching time may be prolonged with the increase in the size of the membrane layer (substrate layer) and with the increase in the thickness of the substrate layer.

In the fourth aspect of the invention, the etching selective ratio of the etching stopper layer to the substrate layer may be at least about 700 for facilitating the fabrication of electron beam masks even when the conditions in processing SiO₂ on an SOI substrate to fabricate electron beam masks are severer with the increase in the size of the membrane layer (substrate layer).

More preferably, the etching selective ratio of the etching stopper layer to the substrate layer is at least about 1000.

The other features of this embodiment are similar to those of the first embodiment of the invention, and as such, will not be described.

The fifth aspect of the invention has been attained for solving all the above-mentioned problems 1-1, 1-2 and 2, and includes an electron beam mask substrate that comprises a substrate layer of a silicon-containing material to form a membrane layer support through backside etching, an etching stopper layer formed on the substrate layer, and a membrane layer of a silicon-containing material formed on the etching stopper layer, wherein;

the etching stopper layer is formed of a metal material or a metal compound such as metal nitride. (Embodiment 5).

The fifth aspect of the invention solves all the above-mentioned problems 1-1, 1-2 and 2.

The metal material includes, for example, those with one or more metals of Cr, Ti, Ta, Zr, Al, Mo and W. The metal compound includes, for example, nitrides, oxides, carbides, oxinitrides, carboxides and carbonitrides of the metal material, such as CrCx, CrNxCy, CrOxCy, CrOx, etc, and their mixtures. The carbon compound includes carbon nitride, etc.

The sixth and seventh aspects of the invention have been attained for solving all the above-mentioned problems 1-1, 1-2 and 2 and for obtaining additional advantages.

In the sixth and seventh aspects of the invention, the etching stopper layer is formed of a chromium compound or a predetermined metal compound (especially, the etching stopper layer is any of chromium nitride (CrN), titanium nitride (TiNx), tantalum nitride (TaNx), zirconium nitride (ZrNx), molybdenum nitride (MoNx) and tungsten nitride (WNx)), and a silicon layer is formed on it through vacuum evaporation to fabricate the substrate. In these aspects, the etching selectivity in backside and surface dry-etching of the substrate is remarkably improved, and this has enabled easy fabrication of large-size electron beam masks that could not be fabricated with ease from related art SOI substrates. The membrane stress of these metal nitride films may be controlled to nearly zero (0) by forming the films through sputtering in a mode assisted by nitrogen gas. Thus formed, in addition, the films are free from a problem of compression stress change (e.g., −50 to −100 MPa) that may be caused by surface oxidation or the like after the film formation. In particular, the membrane stress of the chromium nitride (CrN) film (that comprises nitrogen and chromium as the essential ingredients) may be readily controlled to nearly zero (0) by forming the film through sputtering in a mode assisted by nitrogen gas, and the membrane stress change relative to the change of the sputtering condition such as the chamber pressure may be suppressed low. Further, the chromium nitride film thus formed is free from the problem of compression stress change to be caused by surface oxidation or the like after the film formation.

Moreover, the material of the etching stopper material may be a low-stress material that gives a membrane stress falling within a range of about ±30 MPa, or a low-stress material capable of controlling the membrane stress to fall within a range of about ±30 MPa, and, in addition, its etching selective ratio to the silicon-containing substrate material is at least about 1000. Accordingly, these aspects of the invention all resolve the problem about the membrane stress of the etching stopper layer, the problem about the etching selective ratio of the etching stopper layer, and the problem about the apparatus limitation in backside processing, and enable fabrication of large-size masks (for example, masks larger than 4 inches, especially those not smaller than 8-inch masks). Further, selective removal of the etching stopper layer formed of the material of the type is easy, and, in addition, the etching rate of the layer is high, and the in-plane etching rate uniformity thereof is good. Other advantages, in addition to those just described, are that the etching stopper layer formed of the material of the type has good dry-etching resistance in both backside and surface etching, and has chemical resistance and thermal stability, and the material can stably form films of high quality. Accordingly, large-size masks of high quality can be fabricated.

For producing an electron beam exposure mask from the substrate having the material embodiment as in the above-mentioned sixth and seventh aspects of the invention, it is desirable that the essential dry-etching gas for mask-patterning the membrane layer is any of sulfur hexafluoride (SF₆) or carbon tetrafluoride (CF₄) when a resist is used for the etching mask, but is any of silicon tetrachloride (SiCl₄), hydrogen chloride (HCl), hydrogen bromide (HBr) or hydrogen iodide (HI) when silicon dioxide (SiO₂) is used for the etching mask, and one or more fluorine-containing gases (preferably at least two gases mixed, or at least two gases alternately introduced into the chamber) selected from SF₆, C₄F₈, C₃F₈, C₄F₆, C₂F₆ and C₅F₈ are used in backside dry-etching. The method enables high resolution in mask production (Embodiment 10).

In the first to seventh aspects of the invention mentioned above, the membrane stress of the etching stopper layer is preferably within a range of about ±20 MPa (+ indicates tensile stress, and − indicate tensile stress). In this embodiment, the pattern positioning accuracy after the mask processing may be within the required range (misregistration: at most 20 nm). More preferably, the membrane stress of the etching stopper layer is within a range of about ±5 MPa (+ indicates tensile stress, and − indicate tensile stress).

In the first to seventh aspects of the invention mentioned above, the stress of the membrane layer or the membrane layer for mask patterning is preferably from about +0.2 to about +20 MPa (+ indicates tensile stress). In this embodiment, the pattern positioning accuracy after the mask processing may be within the required range. More preferably, the membrane stress of the membrane layer or the membrane layer is from about +0.2 to about +10 MPa (+ indicates tensile stress).

In the first to seventh aspects of the invention mentioned above, the etching stopper layer is preferably formed of a polycrystalline material or an amorphous material, or a mixed crystal of a polycrystalline material and an amorphous materials, for reducing the membrane stress of the layer.

Also, in the first to seventh aspects of the invention mentioned above, the membrane layer is preferably formed of a polycrystalline material or an amorphous material, or a mixed crystal of a polycrystalline material and an amorphous materials, for reducing the membrane stress of the layer.

The eighth aspect of the invention includes an electron beam mask blank, which is produced through backside etching of the electron beam mask substrate of any of the first to seventh aspects of the invention mentioned above (Embodiment 8).

In the invention, the membrane layer has a thickness of 2 μm or so and is thin, and therefore, it is desirable that the membrane layer is reinforced by forming struts at predetermined intervals on its backside, prior to backside etching (see FIG. 3). For example, in an 8-inch mask, struts must be formed at intervals of 1 mm on the back face of the thin and broad membrane layer having a thickness of about 2 μm so as to reinforce the layer.

In the invention, the backside etching may be effected in a mode of dry etching, and it is desirable to form non-tapered vertical struts on the back face of the membrane layer for enlarging the mask patterning region.

The ninth aspect of the invention includes an electron beam mask, which is produced through backside etching of the electron beam mask substrate of any of the first to seventh aspects of the invention mentioned above, combined with surface etching thereof to form a mask pattern (Embodiment 9).

In stencil-type EPL masks and LEEPL masks, through-holes are formed in the membrane layer to form the mask pattern. In membrane-type EPL masks, an electron beam scatterer layer is formed on the membrane layer, and this is patterned to form the mask pattern.

In the masks, alignment marks and others may be formed.

Examples of embodiments of the invention using the aforementioned teachings are described below.

### EXAMPLE 1

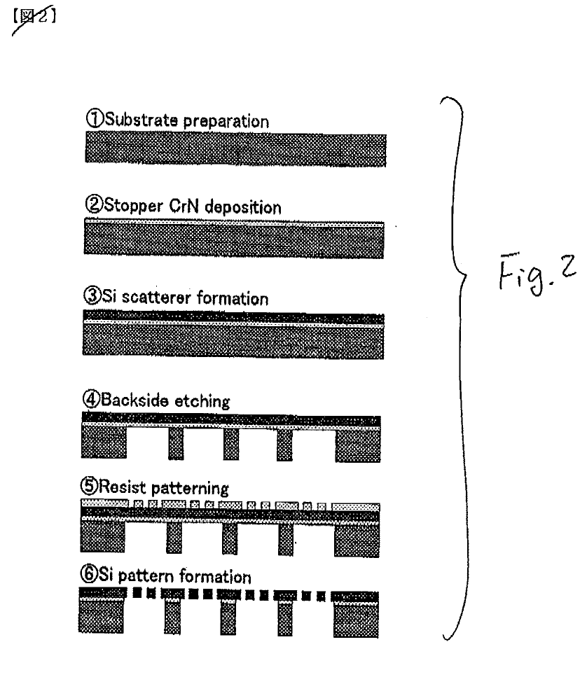

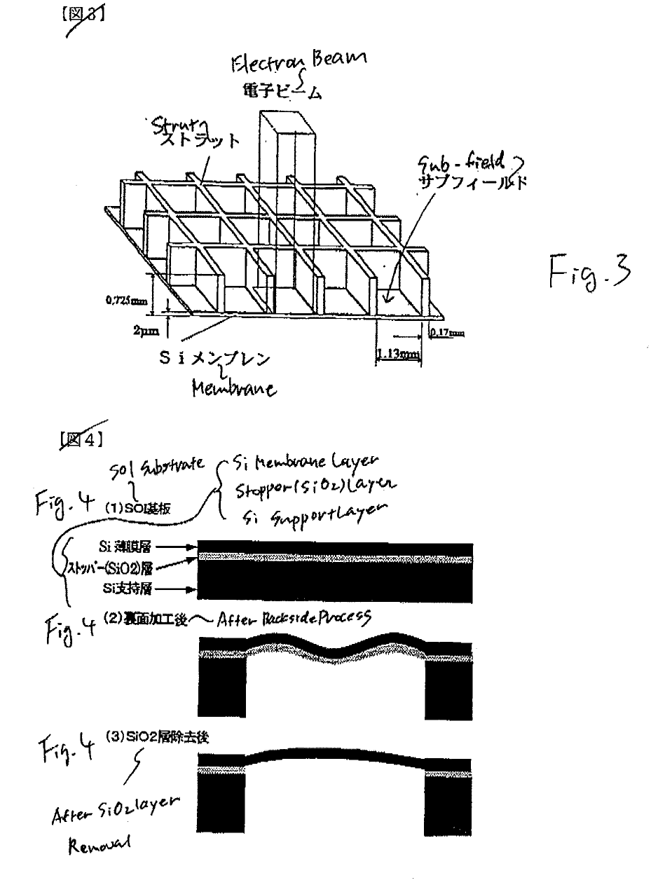

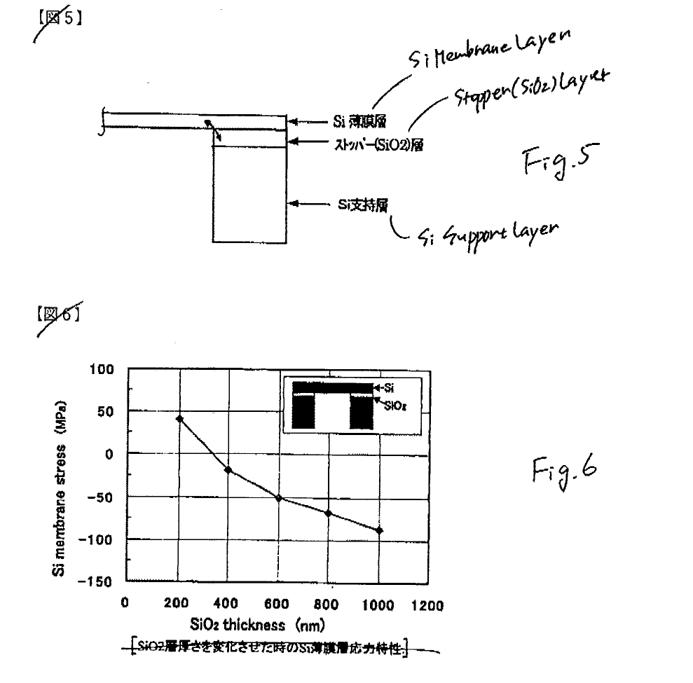

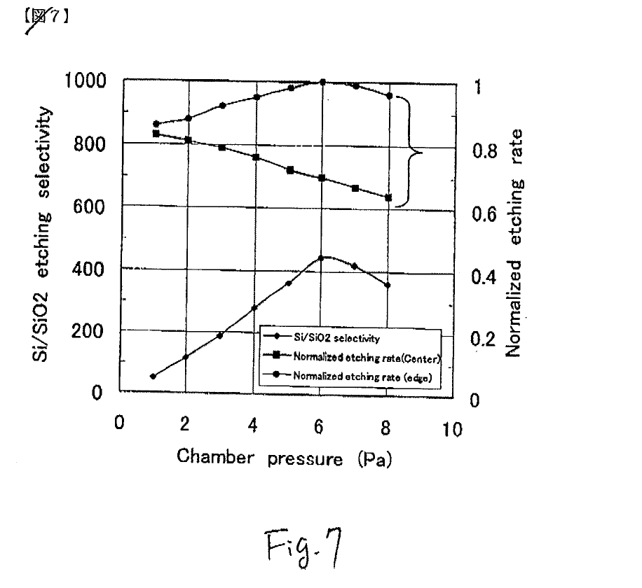

An Si wafer was used for the base substrate (FIG. 2<1>), and a CrN layer and an Si layer were formed in order through vacuum evaporation (PVD, CVD) to construct a mask substrate (FIG. 2 <2>, <3>). First the mask substrate (having the struts as in FIG. 3) was etched on the backside thereof (FIG. 2<4>). For the etching mask in this step, usable is any of resist, SiO₂, various metals such as Cr, Ti, Ta, Zr, Mo, W, as well as the above-mentioned chromium nitride (CrN), titanium nitride (TiNx), tantalum nitride (TaNx), zirconium nitride (ZrNx), molybdenum nitride (MoNx), tungsten nitride (WNx), etc. For the backside etching, SF₆ was used for the essential etching gas, and this was combined with CxFy gas for etching profile control. Regarding the gas introduction mode, a mixed gas of the two was introduced into the chamber, or SF₆ and CxFy were alternately introduced thereinto.

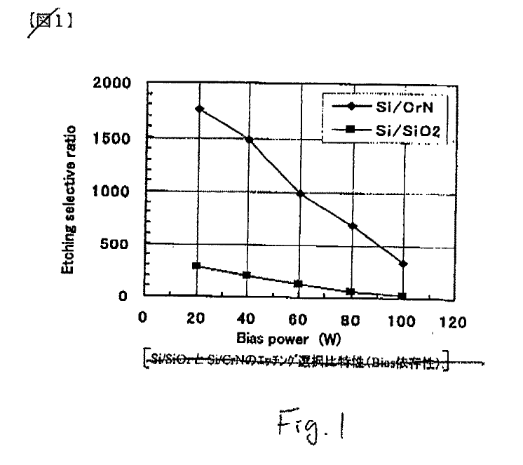

FIG. 1 shows the etching selectivity in this Example, in which CrN was used for the stopper, and SF₆ and CxFy were alternately introduced into the chamber. In FIG. 1, the bias applied to the substrate is the parameter. Apart from it, the present inventors found that the etching resistance of CrN is much higher than that of SiO₂ under any condition. The Si/CrN etching selective ratio was at least 1000 when the bias power was at most 60 W. The membrane stress of the stopper film of a metal nitride such as CrN may be controlled to fall within a range of ±10 MPa by optimizing the film-forming condition such as the nitrogen partial pressure in film formation, and therefore controlling stress of the metal nitride stopper layer during mask fabrication is facilitated.

After the backside processing of the substrate, a resist material was formed on the surface of the substrate, and then this was patterned to form a mask pattern with alignment control in the backside-etched membrane area (FIG. 2<5>). For this patterning, electron beam writing technology was employed. Via the etching mask of the resist, the Si membrane layer was etched to form a mask pattern, using SF₆ as the essential etching gas (FIG. 2 <5>, <6>). In this stage, the Si/Cr etching selective ratio was 240.

Next, the etching mask layer and the stopper CrN layer were selectively removed. The process was efficient and readily gave a large-size (8-inch) stencil-type EPL mask (FIG. 2<6>). The pattern size on the mask was at least 200 nm, and this corresponds to 50 nm on wafer.

### EXAMPLE 2

An Si wafer was used for the base substrate, and a TiN layer and an Si layer were formed in order through vacuum evaporation (PVD, CVD). On the Si layer, an SiO₂ layer was formed through CVD to construct a mask substrate. First the mask substrate was etched on the backside thereof. For the backside etching, SF₆ was used as the essential etching gas, and this was combined with a CxFy gas for etching profile control. SF₆ and CxFy gases were alternately introduced into the chamber. The Si/TiN etching selective ratio was 2600. The stress of the TiN stopper layer itself was +4 MPa.

After the backside processing of the substrate, a resist material was formed on the surface of the substrate, and then this was patterned to form a mask pattern with alignment control in the backside-etched membrane area. For this patterning, electron beam writing technology was used. Via the etching mask of the resist, the SiO₂ layer was etched to form a mask pattern, using CF₄ as the essential etching gas, and then the Si membrane layer was dry-etched to form a mask pattern using HI as the essential etching gas. In this stage, the Si/TiN etching selective ratio was 120.

Next, the etching mask layer and the stopper TiN layer were selectively removed. The process was efficient and readily gave a large-size (8-inch) mask.

### REFERENCE EXAMPLE 1

In Example 1, chlorine (Cl₂) was used for the mask pattern etching gas. However, the Si/CrN etching selective ratio was only 3, and the process did not give an 8-inch mask.

Although the invention has been described in its preferred embodiments, it is understood that the invention is not limited to the specific above-described embodiments. For example, in the above-mentioned Examples, the order of the working steps are not specifically defined so far as to limit other processes known to those of ordinary skill in the art that may finally give the intended mask structure of good quality.

Also, before processed, substrates of any type having an etching mask layer and other layers for etching are all within the scope of the mask substrate of the invention. The mask substrate of the type is generally encompassed within the concept of mask blanks. In addition, the mask substrates that arc under backside processing operation are all within the scope of the mask blank of the invention.

The invention provides a tough electron beam mask for which the membrane stress of the etching stopper is specifically so controlled as to reduce the deformation of the layer structure, and provides an electron beam mask substrate and an electron beam mask blank that are for producing the electron beam mask.

The invention also provides an electron beam mask substrate and an electron beam mask blank for which the etching stopper is specifically so improved as to exhibit good characteristics in backside processing, and provides an electron beam mask produced from them.

The invention further provides an electron beam mask substrate and an electron beam mask blank capable of giving large-sized electron beam masks in which the size of the substrate is large (for example, 8-inch-size), and provides an electron beam mask produced from them.

What is claimed is:

1. An electron beam mask substrate comprising a substrate layer to form a membrane layer support through backside etching, an etching stopper layer formed on the substrate layer, and a membrane layer formed on the etching stopper layer, wherein;
when a tensile stress of the membrane layer is reduced with a reduction in a thickness of the membrane layer so that a membrane part comprising the membrane layer and the etching stopper layer is deformed by backside etching processing, and/or the membrane layer is deformed within a range not satisfying a mask pattern positioning accuracy by removal of the etching stopper layer, owing to the influence of a stress of the etching stopper layer thereon,
then a membrane stress of the membrane layer and a membrane stress of the etching stopper layer are so correlated that the membrane part is not deformed during backside processing, and/or so correlated that the membrane layer is not deformed over the range satisfying the mask pattern positioning accuracy during removal of the etching stopper layer.

2. An electron beam mask substrate comprising a substrate layer to form a membrane layer support through backside etching, an etching stopper layer formed on the substrate layer, and a membrane layer formed on the etching stopper layer, wherein;
an etching selective ratio of the etching stopper layer to the substrate layer is enlarged to allow latitude in dry-etching conditions in backside dry-etching.

3. An electron beam mask substrate comprising a substrate layer of a silicon-containing material to form a membrane layer support through backside etching, an etching stopper layer formed on the substrate layer, and a membrane layer of a silicon/containing material formed on the etching stopper layer, wherein;
the etching stopper layer is formed of a material operable to provide at least one of a membrane stress falling within a range of about ±30 MPa after backside etching, and controlling the membrane stress after backside etching to fall within a range of about ±30 MPa.

4. An electron beam mask substrate comprising a substrate layer of a silicon-containing material to form a membrane layer support through backside etching, an etching stopper layer formed on the substrate layer, and a membrane layer of a silicon-containing material formed on the etching stopper layer, wherein;
the etching stopper layer is formed of a material of which the etching selective ratio to the silicon-containing substrate layer is at least about 700.

5. An electron beam mask substrate comprising a substrate layer of a silicon-containing material to form a membrane layer support through backside etching, an etching stopper layer formed on the substrate layer, and a membrane layer of a silicon-containing material formed on the etching stopper layer, wherein;
the etching stopper layer is formed of any one selected from a metal material, a metal compound, carbon and a carbon compound, or a combination thereof.

6. The electron beam mask substrate as claimed in claim 5, wherein the metal compound is a chromium compound.

7. The electron beam mask substrate as claimed in claim 5, wherein the metal compound is any one selected from compounds with any of titanium (Ti), tantalum (Ta), zirconium (Zr), aluminium (Al), molybdenum (Mo) and tungsten (W), or a combination thereof.

8. An electron beam mask blank, which is produced through backside etching of the electron beam mask substrate of claim 1 to form a support.

9. An electron beam mask blank, which is produced through backside etching of the electron beam mask substrate of claim 2 to form a support.

10. An electron beam mask blank, which is produced through backside etching of the electron beam mask substrate of claim 3 to form a support.

11. An electron beam mask blank, which is produced through backside etching of the electron beam mask substrate of claim 4 to form a support.

12. An electron beam mask blank, which is produced through backside etching of the electron beam mask substrate of claim 5 to form a support.

13. An electron beam mask, which is produced through backside etching of the electron beam mask substrate of claim 1, combined with surface etching thereof to form a mask pattern.

14. An electron beam mask, which is produced through backside etching of the electron beam mask substrate of claim 2, combined with surface etching thereof to form a mask pattern.

15. An electron beam mask, which is produced through backside etching of the electron beam mask substrate of claim 3, combined with surface etching thereof to form a mask pattern.

16. An electron beam mask, which is produced through backside etching of the electron beam mask substrate of claim 4, combined with surface etching thereof to form a mask pattern.

17. An electron beam mask, which is produced through backside etching of the electron beam mask substrate of claim 5, combined with surface etching thereof to form a mask pattern.

18. A method for producing an electron beam exposure mask, which comprises processing the electron beam mask substrate of claim 6 for producing the mask, and in which the essential dry-etching gas for mask-patterning the membrane layer is any of sulfur hexafluoride (SF₆) or carbon tetrafluoride (CF₄) when a resist is used for the etching mask, but is any of silicon tetrachloride (SiCl₄), hydrogen chloride (HCl), hydrogen bromide (HBr) or hydrogen iodide (HI) when silicon dioxide (SiO₂) is used for the etching mask, and one or more fluorine-containing gases selected from SF₆, C₄F₈, C₃F₈, C₄F₆, C₂F₆ and C₅F₈ are used in backside dry-etching.

19. A method for producing an electron beam exposure mask, which comprises processing the electron beam mask substrate of claim 7 for producing the mask, and in which the essential dry-etching gas for mask-patterning the membrane layer is any of sulfur hexafluoride (SF₆) or carbon tetrafluoride (CF₄) when a resist is used for the etching mask, but is any of silicon tetrachloride (SiCl₄), hydrogen chloride (HCl), hydrogen bromide (HBr) or hydrogen iodide (HI) when silicon dioxide (SiO₂) is used for the etching mask, and one or more fluorine-containing gases selected from SF₆, C₄F₈, C₃F₈, C₄F₆, C₂F₆ and C₅F₈ are used in backside dry-etching.

20. An electron beam mask substrate comprising a substrate layer to form a membrane layer support through backside etching, an etching stopper layer formed on the substrate layer, and a membrane layer formed on the etching stopper layer, wherein;
a membrane stress of the membrane layer and a membrane stress of the etching stopper layer are so correlated that a membrane part comprising the membrane layer and etching stopper layer is not deformed during backside processing, and/or so correlated that the membrane layer is not deformed over the range satisfying the mask pattern positioning accuracy during removal of the etching stopper layer.
